(19) United States
(12) Patent Application Publication
(10) Pub. No.: US 2005/0270054 A1
(43) Pub. Date: Dec. 8, 2005

(54) Method and apparatus for iddq measuring

(75) Inventor: Johannes Lambertus Hendrikus Van Hees, Nijmegen (NL)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: KONINKLIJKE PHILIPS ELECTRONICES N.V., Eindhoven (NL)

(21) Appl. No.: 10/527,380

(22) PCT Filed: Aug. 6, 2003
(86) PCT No.: PCT/IB03/03513

§ 371 Date: Mar. 11, 2005

(30) Foreign Application Priority Data
Sep. 16, 2002 (EP) 02078798.2

(51) Int. Cl. G01R 31/26

(52) U.S. Cl. 324/765

(57) ABSTRACT

An IDDQ test is applied to an electronic circuit (16). A power supply unit supplies power supply current to the electronic circuit. The output impedance of the power supply unit is adjusted to a value selected for the electronic circuit, the value having been selected so that a resonance circuit (14) that comprises a connection between the power supply unit and the electronic circuit is substantially critically dampened. The current sense element (18) that is used to measure IDDQ current is coupled between an external power supply and a supply input of the power supply unit, so that the current sense element does not affect the output impedance.

The invention relates to a set-up for performing an IDDQ test of an electronic circuit under test, to a measuring apparatus for such a set-up and to a method of performing an IDDQ test.

IDDQ (quiescent (Q) drain (DD) current (I)) testing is a technique to check electronic circuits, in particular CMOS integrated circuits for errors. Such an electronic circuit may draw a considerable amount of supply current when it switches from one state or another, but once the electronic circuit has stabilized after state switching the current drops to a quiescent level that is much smaller than the current during switching. An IDDQ test involves the measurement of this quiescent level of the supply current, which provides an indication of the presence of errors or weaknesses in the electronic circuit. Any supply current may be used for this purpose: although the abbreviation IDDQ might create the suggestion that in this test the current from the positive terminal (VDD) of the power supply is determined, the term IDDQ will be understood to cover any measurement of a supply current, including current from the negative terminal (VSS). When the measured quiescent level exceeds a predetermined level, the electronic circuit is rejected as faulty.

The large ratio between the current during switching and the quiescent current poses problems for the IDDQ test. Generally the test circuit contains a resistance through which the supply current flows and over which a voltage is measured to determine the quiescent current level. Due to the small value of the quiescent current a relatively large resistance is needed for a reliable measurement. Such a large resistance, however, leads to high voltages during switching, which may disturb operation of the test circuit.

U.S. Pat. No. 5,773,990 describes various techniques that address this problem. First of all it describes a prior art technique of including a number of resistors in parallel between the output of a regulated power supply and the electronic circuit under test. Selected ones of the resistors carry the current from the power supply output to the electronic circuit under test, as determined by means of respective switches in series with the resistors. A resistor with a low resistance value is used during state switches of the electronic circuit under test and resistor with a larger resistance value is used during quiescent current measurement. The voltage over this resistor is measured to determine the current. This technique suffers from glitches when switching from one resistor to the other.

As an alternative technique U.S. Pat. No. 5,773,990 describes the use of a regulated current source (high impedance) output of the power supply, with a parallel arrangement of a diode and a resistor connected between the output and the electronic circuit under test. The current from the current source is regulated to maintain a constant voltage at the connection to the electronic circuit under test. The diode clamps high voltage peaks over the resistor during state switching of the electronic circuit under test. The voltage over the resistor is measured to determine the IDDQ current. This test circuit avoids the problems of high voltage drops over the measurement resistor without causing glitches.

None of these techniques take account of the fact that the supply connection to the electronic circuit under test often behaves as an LC resonance circuit. The wiring from the power supply to the electronic circuit under test behaves as an inductance (L). Next to the electronic circuit under test a decoupling capacitance is often included and in any case the electronic circuit under test itself behaves as a capacitance (C) during state switching, because capacitive loads at the output of driver stages have to be charged and discharged.

The resonance behavior of this LC resonance circuit delays the time at which the IDDQ current can be measured. In order to minimize this delay it is desirable that the output impedance of the power supply should be selected so that this LC resonance circuit is critically damped. This is not the case when a regulated power supply is used with effectively nearly zero output impedance. Nor is the resistance value that should be used to obtain critical damping consistent with the relatively large resistance value needed for reliable measurement of the small IDDQ current.

Among others, it is an object of the invention to provide for a method of performing an IDDQ test of an electronic circuit that allows a minimization of the delay before the IDDQ current can be measured.

Among others, it is an object of the invention to provide for a method of performing an IDDQ test of an electronic circuit in which the output impedance of the test circuit can be chosen to achieve optimal speed, without affecting the sensitivity of current measurement.

Among others, it is another object of the invention to provide for an IDDQ test system in which any voltage drop used for measuring the quiescent supply current does not affect regulation of the power supply voltage or the output impedance of the power supply circuit.

Among others, it is a further object of the invention to provide for a sensitive measurement of quiescent current.

The method according to the invention is set forth in claim 1. According to the invention the output impedance of the power supply unit is programmed to a value that is selected for the electronic circuit under test so as to substantially minimize the delay time due to resonance of the connection between the circuit under test and the power supply unit. The programmed output impedance may be set to the required impedance value once for testing a series of test of different electronic circuits of the same type or once per electronic circuit, or even a plurality of times for the same electronic circuit, each time when the electronic circuit is set to a respective state to perform a different IDDQ test.

The system according to the invention is set forth in claim 4. According to the invention the current sensing element is included in a power supply line between an external power supply source and the power supply regulating circuit that supplies power to the electronic circuit under test. Thus, any voltage drop over the current sensing element is kept outside the regulating loop of the regulating circuit. In contrast to the known IDDQ test circuits the sensing element is not in the connection between the power supply and the electronic circuit under test. Thus it affects neither the regulation not the output impedance of the power supply circuit. The output impedance of the power supply circuit can be set independently of the sensing element, so as to provide minimize the delay of the LC resonance circuit between the power supply and the electronic circuit under test.

In an embodiment a current source is included in parallel with the current sense element and the current through current source is adjusted to a value so that substantially no current flows through the current sense element when the electronic circuit under test draws not current. Thus, a sensitive measurement can be performed with the current sense element.

In a further embodiment the supply reference terminals of the electronic circuit under test and the power supply unit float with respect to one another. The current sense element draws and senses current from the reference terminal of the electronic circuit. Thus current from the supply reference of the electronic circuit flows to or from the power supply unit through the current sense element and the electronic circuit under test. The current through the current source is regulated so that substantially no other current needs to from the power supply unit to the reference of the electronic circuit under test to keep the references assume a predetermined voltage offset with respect to one another. Thus it is ensured that the current to the electronic circuit and the current through the current sense element are substantially equal.

In another embodiment the current through the current source is adjusted in a calibration phase when the electronic circuit under test is decoupled from the power supply.

In another embodiment the power supply unit contains a transistor coupled to the output of the power supply unit in emitter follower configuration (or source follower configuration in case of a FET). With a current source the quiescent current through the transistor is set to a programmable value. This allows adjustment of the output impedance of the power supply unit, for example to the value needed for critical damping of the resonant connection to the electronic circuit under test. The voltage at the control electrode of the transistor is regulated so that on average the power supply unit supplies a predetermined output voltage.

These and other advantageous aspects of the system, method and circuit according to the invention will be described in more detail using the following figures.

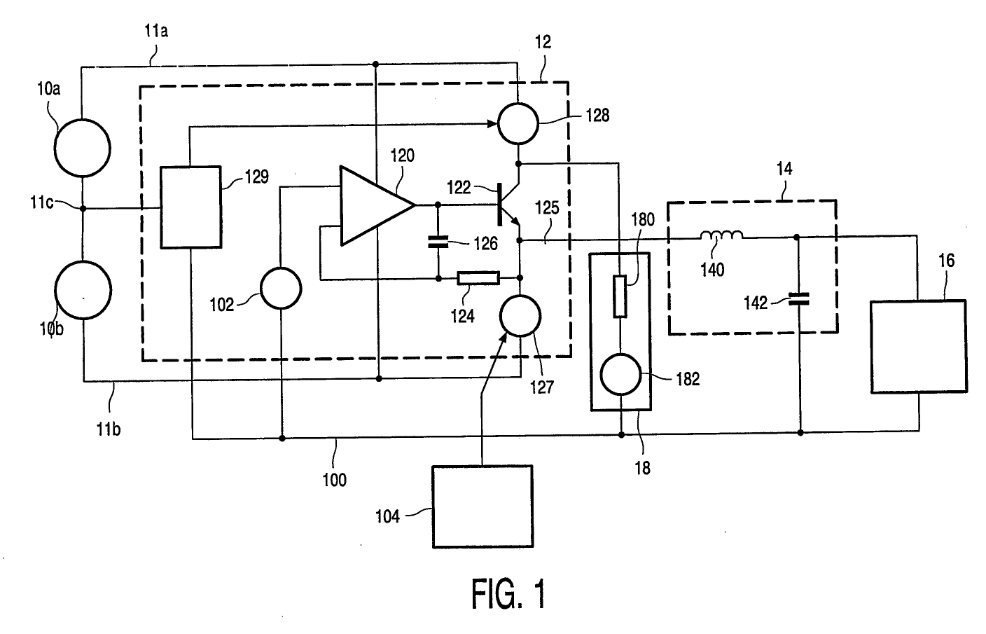

FIG. 1 shows an IDDQ test system;

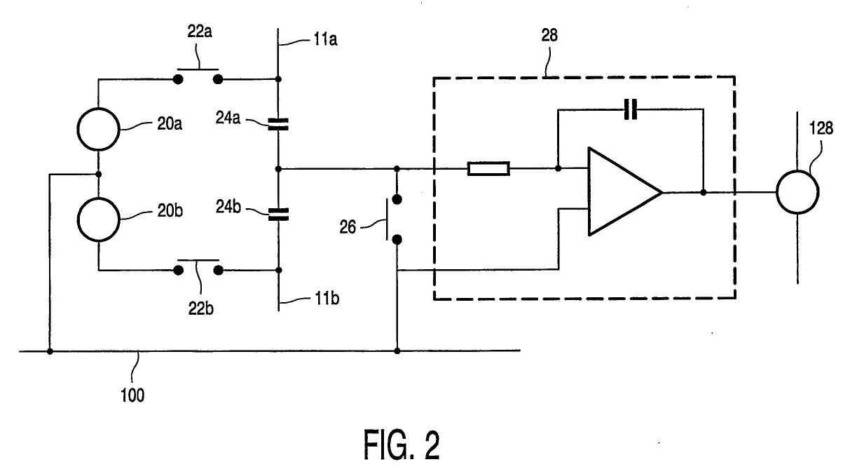

FIG. 2 shows a power supply configuration; and

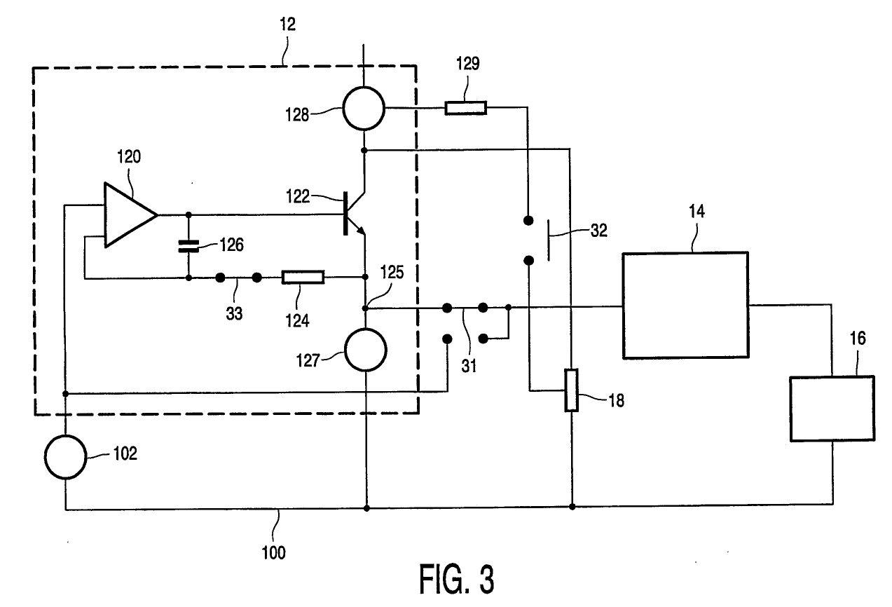

FIG. 3 shows an IDDQ test system.

FIG. 1 shows an IDDQ test system, comprising a common reference terminal 100, external power supply voltage sources 10a, 10b, a power supply regulating circuit 12, a power supply connection 14, an electronic circuit under test 16, a current sense element 18 and a control circuit 104. The voltages at the terminals of power supply voltage sources 10a,b float with respect to common reference terminal 100. Power supply voltage sources 10a,b are coupled in series. The terminals of this series arrangement serve as a positive supply terminal 11a and a negative supply terminal 11b of regulating circuit 12 respectively. An output of regulating circuit 12 is coupled to electronic circuit under test 16 via power supply connection 14. Electronic circuit under test 16 is coupled between power supply connection 14 and common reference terminal 100. Power supply connection 14 is shown to contain an inductor 140 in series between the output of regulating circuit 12 and electronic circuit under test 16 and a capacitor 142 in parallel with electronic circuit under test 16. Inductor 140 and capacitor 142 are shown symbolically to make the electric effect of connection 14 clear. Inductor 140 symbolizes the wiring inductance of connection 14 and capacitor 142 at least partly represents the capacitive behavior of electronic circuit under test 16 as well as any decoupling capacitance.

In operation, regulating circuit 12 on average supplies constant voltage to electronic circuit under test 16. In order to test electronic circuit under test 16, current sense element 18 determines whether the current drawn by electronic circuit under test 16, when that electronic circuit under test 16 is in a stable state, is below a predetermined threshold value. If not, an error signal is generated and the electronic circuit under test 16 is rejected as faulty. Generally, a plurality of such tests is performed under control of control circuit 104 (through input connections to electronic circuit under test 16 which have been omitted from FIG. 1 for the sake of clarity), each time with electronic circuit under test 16 in a different logic state. Different logic states in the sense used here are realized by applying different input signals to the electronic circuit under test 16 and/or by switching memory elements in electronic circuit under test 16 to different states.

When electronic circuit under test 16 switches from one state to another, it temporarily draws more supply current from regulating circuit 12. The time dependence of this current in response to a change of state corresponds to the time dependence involved in charging capacitor 142. Eventually the current settles to the level of quiescent current drawn by electronic circuit under test 16, but before the current settles a time dependent variation occurs. The IDDQ measurement has to be deferred substantially until the circuit has settled, i.e. until this time dependence is over.

Due to the combination of inductor 140 and capacitor 142 this time dependent variation may have an oscillatory nature when the output impedance of regulating circuit 12 is very low and on the other hand it may have a long RC charging time when the output impedance is very high. Preferably the settling time is minimized by setting the output impedance of regulating circuit 12 to a value R that substantially causes critical damping of the LC circuit in connection 14, i.e. by setting

An optimum is reached when R has exactly this value, but of course near optimal performance occurs also for a range of values of R near the optimal value.

Generally speaking the values of L and C, and therefore the optimal value R depend on the properties of electronic circuit under test 16 and the connecting wiring that is used to supply power to the electronic circuit under test 16. When a series of copies of the same type of electronic circuit under test 16 is tested, therefore, control circuit 104 preferably adjusts the output impedance of regulating circuit 12 at least once for the series to substantially the optimal value R, which may be determined experimentally.

Under some circumstances, the optimum value may even depend on the state to which electronic circuit under test 16 is switched or on the state between which electronic circuit under test 16 is switched. In this case, control circuit 104 may even reprogram the impedance of regulating circuit 12 upon switching to a new state, at least for some of the switches between states.

Regulating circuit 12 contains a series arrangement of a first current source 128, the main current channel of a transistor 122 and a second current source 127 between the positive and negative supply terminals 11a,b. A node 125 between the main current channel of transistor 122 and second current source 127 forms the output of regulating circuit 12. Control circuit 104 is coupled to a control input of second current source 127. Regulating circuit 12 furthermore contains a differential amplifier 120, a capacitance 126 and a resistance 124. Differential amplifier 120 receives its power supply from power supply terminals 11a,b. A reference voltage source 102 is coupled between common reference terminal 100 and a positive gain input of differential amplifier 120. An output of differential amplifier 120 is coupled to a control electrode of transistor 122. Output 125 of regulating circuit 12 is coupled back to a negative gain input of differential amplifier 120 via resistor 124. The negative gain input of differential amplifier 120 is coupled to the output of differential amplifier 120 via capacitor 126. Regulating circuit 12 furthermore contains a current control amplifier 129 which is coupled to a node 11c between the power supply sources 10a,b to sense a net difference between the currents flowing through the power supply sources 10a,b. Current control amplifier 129 has an output coupled to a control input of first current source 128. Current sense element 18 contains a measurement voltage source 180 and a current measurement element 182 in series between common reference terminal 100 and a node between first current source 128 and the main current channel of transistor 122.

In operation differential amplifier 120 regulates the voltage at the control electrode of transistor 122 so that the time averaged voltage difference between output 125 and common reference terminal 100 substantially equals the reference voltage Vref of reference voltage source 102. This holds only for the lower frequency variations of the voltage at output 125. At higher frequencies (for example higher than 200 Hz) the combination of resistor 124 and capacitance 126 decouples the feedback path from output 125 to the negative gain input of differential amplifier 120.

The net difference between the currents through power supplies 10a,b is equal to the net current that is supplied to or drawn from regulating circuit 12 by current sense element 18 and connection 14. Current control amplifier 129 regulates the current from first current source 128 so that the net difference between the currents drawn from power supplies 10a,b becomes zero when the voltage at node 11c assumes the same voltage as common reference terminal 100. As a result, the measurement current supplied by current sense element 18 must equal the current supplied to electronic circuit under test 16 via connection 14. This current is measured by current measurement element 182. Current measurement element 182 contains for example a resistor (not shown) through which the measurement current flows and a comparator circuit (not shown) to compare the voltage across this resistor with a threshold value, the electronic circuit under test 16 being rejected when the measurement current exceeds a predetermined value under quiescent conditions.

Control circuit 104 sets the quiescent current through the main current channel of transistor 122 so that the impedance presented by transistor 122 to output 125 substantially equals the impedance that causes the fastest possible response by the LC resonance circuit formed by inductance 140 and capacitance 142. Preferably the impedance is set to cause critical damping the LC resonance circuit. The precise value of the impedance that is needed for this purpose depends the electronic circuit under test 16 and the way it is connected to the output 125, in particular on the wiring and any decoupling capacitance.

Control circuit 104 uses second current source 127 to control the impedance presented by transistor 122. Second current source 127 substantially determines the current through the main current channel of transistor 122 in the quiescent state. For a bipolar transistor 122 this impedance Z is inversely proportional to the current I supplied by second current source 127: Z=Vo/I Ohms, with Vo=0.025 Volts at room temperature. When a MOS transistor is used for transistor 122 this impedance also depends on the current although it is generally not a linear function of the current I.

As a result, the circuit of FIG. 1 allows control circuit 104 to set the impedance at output 125 by means of the current through second current source 127 without affecting the measurement current through current sense element 18 with which an excess quiescent current is detected. The impedance of current sense element 18 does not affect the time-critical adjustment of the impedance at output 125. Nor does any voltage drop over current sense element 18 affect the operation of the regulating loop in regulating circuit 12.

Floating supply voltage sources 10a,b may be implemented using batteries, or using separate transformer—rectifier circuits or any other type of floating voltage source.

FIG. 2 shows an implementation of floating supply voltage sources 10a,b and current control amplifier 129. In this implementation batteries or separate transformers are not needed. The implementation contains primary voltage sources 20,a,b power supply switches 22a,b power supply capacitors 24a,b a short circuit switch 26 and an integrating amplifier 28. In addition, FIG. 2 shows the positive and negative terminal 11a,b and first current source 128. The primary voltage sources 20a,b have one terminal in common, which is coupled to common reference 100. The other terminals of primary voltage sources 20a,b are coupled to the positive and negative terminal 11a,b via respective ones of the power supply switches 22a,b respectively. The positive and negative terminal 11a,b are coupled to common terminal 11c via respective ones of the power supply capacitors 24a,b. Common terminal 11c is coupled to an input of integrating amplifier 28, whose output is coupled to the control input of first current source 128. Short circuit switch 26 is included between common node 11c and common reference 100.

In operation, power supply switches 22a,b are periodically switched on and off under control of a clock circuit (not shown). The clock circuit defines a number of periodically repeated phases of a clock cycle. In a first phase power supply capacitors 24a,b are recharged by making power supply switches 22a,b conductive and current control amplifier 28 is deactivated by making short circuit switch 26 conductive. In a second phase, power supply switches 22a,b and short circuit switch 26 are non-conductive. In this second phase, power supply capacitors 24a,b serve as power supply sources 10a,b and integrating amplifier 28 integrates the net current from common node 11c and from the integrated net current integrating amplifier generates a control signal for first current source 128. During switching between the first and second phase and back a third and fourth phase occurs in which short circuit switch 26 is conductive and power supply switches 22a,b are non-conductive. The third and fourth phase ensure that control of the current from first current source 128 is not affected by glitches during switching between the first and second phase.

FIG. 3 shows a second embodiment of the test system. In comparison with the system of FIG. 1 floating voltage sources 10a,b have been omitted. In the embodiment of FIG. 3 all components may operate using the same external power supply source. Furthermore, current control amplifier 129 has been omitted. An integrator 30 and a first, second and third switch 31, 32, 33 have been added. A control circuit 35 controls the switches 31, 32, 33. First switch 31 couples the electronic circuit under test either to output 125 or to reference voltage source 102. A series arrangement of second switch 32 and integrating circuit 30 couple an output of current measurement element 182 to the control input of first current source 128. Third switch 33 is coupled in series with resistor 124.

In operation the circuit operates in different phases. During a calibrating phase, first switch 31 couples electronic circuit under test 16 to reference voltage source 102. Second switch 32 is conductive, which causes integrator 30 to control the current through first current source 128 so that no current flows through current sense element 18. Third switch 33 is conductive so that output 125 is at the voltage level of reference voltage source 102.

In a measuring phase first switch 31 couples the electronic circuit under test 16 to the output 125. The second and third switch 32, 33 are made non-conductive. In this measuring phase a current equal to the current to electronic circuit under test 16 flows through current sense element 18. Current sense element 18 senses the current when the IDDQ current has to be measured, so as to test the circuit.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The invention can be implemented by means of hardware comprising several distinct elements. In the device claim enumerating several means, several of these means can be embodied by one and the same item of hardware. The mere fact that certain measures are recited in mutually different dependent claims does not indicate that a combination of these measures cannot be used to advantage.

1. A method of performing an IDDQ test of an electronic circuit, the method comprising
using a power supply unit to supply power supply current to the electronic circuit;
adjusting an output impedance of the power supply unit to a value selected for the electronic circuit, the value having been selected so that a resonance circuit that comprises a connection between the power supply unit and the electronic circuit is substantially critically dampened;
measuring IDDQ current with a current sensing element that senses a value of the current supplied to the electronic circuit between an external power supply source and the power supply regulating circuit that supplies power to the electronic circuit under test, outside a part of the power supply unit that affects the output impedance.

2. A method according to claim 1, wherein said power supply unit contains a regulating loop, for regulating a supply voltage applied to the electronic circuit at least during measurement of the IDDQ current, said measuring being performed on an incoming supply current that the power supply unit draws to provide the regulated voltage to the electronic circuit.

3. A method according to claim 1, wherein a further incoming supply current is supplied to the power supply unit in parallel with said incoming supply current, the method comprising regulating the further incoming supply current to a level equal to a consumed current that is consumed by the power supply unit.

4. An IDDQ test system, comprising
an electronic circuit under test;
a power supply unit, with a power supply output coupled to the electronic circuit under test, the power supply unit comprising a regulating loop for regulating a power supply voltage applied to the electronic circuit under test, the power supply unit having a current input for receiving an incoming supply current that the supply unit draws to supply the power supply voltage;
a current sense element arranged to measure at least part of the incoming supply current and to generate an IDDQ error signal dependent on a level of said part of the incoming supply current.

5. An IDDQ test system according to claim 4, comprising
a first current source coupled to the current input of the power supply unit in parallel with the current sense element; and
an adjustment circuit arranged to adjust a further part of the incoming supply current that is supplied by the first current source to a level of consumed current that is consumed by the power supply unit.

6. An IDDQ test system according to claim 4, wherein the power supply unit comprises
a transistor with a control input and having a main current channel coupled between the current input and an output that is coupled to the electronic circuit under test;
a programmable current source coupled to the output so as to substantially set a quiescent through the main current channel of the transistor to a programmable value;
a feedback circuit coupled between the output and the control input of the transistor, so as to regulate a voltage at the output with the transistor in source follower or emitter follower operation.

7. An IDDQ test system according to claim 4, wherein the power supply unit comprises
a common reference connection, the electronic circuit under test conducting quiescent power supply current form the output of the power supply unit to the common reference connection, the current sense element being coupled between the current input and the common reference connection;
a series arrangement of a first and second power supply that float with respect to the common reference connection at least for part of the time, the power supply unit being fed from terminals of said series arrangement;
a further current source coupled to the current input of the power supply unit in parallel with the current sense element, the first current source drawing current from one of the terminals of the series arrangement;
a current control circuit, comprising a current path from a node between the first and second power supplies and the common reference connection, the current control circuit having an output coupled to a control input of the further current source, the current control circuit being arranged to regulate the current through the further current source so that substantially no current flows through the current path.

8. An IDDQ test system according to claim 4, wherein the power supply unit comprises
a further current source coupled to the current input of the power supply unit in parallel with the current sense element, the first current source drawing current from one of the terminals of the series arrangement;
a current control circuit, the current control circuit having an output coupled to a control input of the further current source, the current control circuit being arranged to regulate the current through the further current source so that substantially no current flows through current sense element during a calibration phase when the electronic circuit under test is decoupled from the output of the power supply unit.

9. An IDDQ test apparatus, comprising
a power supply output for connecting an electronic circuit under test;
a power supply unit, with a power supply output coupled to the power supply output, the power supply unit comprising a regulating loop for regulating a power supply voltage applied to the electronic circuit under test, the power supply unit having a current input for receiving an incoming supply current that the supply unit draws to supply the power supply voltage;
a current sense element arranged to measure at least part of the incoming supply current and to generate an IDDQ error signal dependent on a level of said part of the incoming supply current.
